(19) United States
(12) Patent Application Publication
(10) Pub. No.: US 2021/0190968 A1
(43) Pub. Date: Jun. 24, 2021

(54) SELF-CALIBRATING INFRASTRUCTURE SENSOR

(71) Applicant: Continental Automotive Systems, Inc., Auburn Hills, MI (US)

(72) Inventor: Vivian Swan, Auburn Hills, MI (US)

(21) Appl. No.: 16/725,585

(22) Filed: Dec. 23, 2019

(51) Int. Cl. G01S 19/47; G01R 33/02; G01C 9/02; G01S 13/931

(52) U.S. Cl. CPC G01S 19/47; G01R 33/02; G01S 2013/9316; G01S 13/931; G01S 2013/9323; G01C 9/02

(57) ABSTRACT

A self-calibrating sensor system includes a sensor configured to be mounted to a static component. The sensor includes a GPS antenna configured to detect a position of the sensor. An inclinometer is configured to detect a pitch of the sensor. A magnetometer is configured to detect an orientation of the sensor.

### BACKGROUND

Smart infrastructure systems may gather data regarding a particular environment, such as information regarding a number of pedestrians or vehicles detected in the particular environment. These infrastructure systems may include various types of sensors that are mounted to infrastructure (traffic lights, signs, parking meters, etc.) near intersections, along roads, and on buildings.

Infrastructure sensor systems may communicate with nearby vehicles. Vehicle to outside systems (V2X) communication, such as vehicle-to-vehicle (V2V) communication and vehicle-to-infrastructure (V2I) communication are-increasingly used as inputs to improve vehicle safety and convenience, particularly for driving-assistance systems and automated driving. Infrastructure sensing devices involved with V2X communication include sensing devices which sense objects within the field of view of the devices. Such a sensing device may, for example, be integrated with a traffic light or be a standalone object mounted on a pole, building or other structure. Despite infrastructure sensing devices being stably mounted and/or secured, the location of such devices may change over time. For example, the position (pitch, altitude and orientation) sensor may vary based upon temperature, wind, the weight of snow or ice on the sensor or the structure on which the traffic light is mounted, etc. In addition, vision based sensors need to be recalibrated from time to time.

### SUMMARY

In one exemplary embodiment, a self-calibrating sensor system includes a sensor configured to be mounted to a static component. The sensor includes a GPS antenna configured to detect a position of the sensor. An inclinometer is configured to detect a pitch of the sensor. A magnetometer is configured to detect an orientation of the sensor.

In a further embodiment of any of the above, the sensor is one of a radar sensor, a lidar sensor, and a camera.

In a further embodiment of any of the above, the static component is an infrastructure component.

In a further embodiment of any of the above, the sensor is configured to be in communication with a computing module.

In a further embodiment of any of the above, the computing module is configured to store the position, pitch, and orientation of the sensor.

In a further embodiment of any of the above, the computing module is configured to communicate with a vehicle.

In a further embodiment of any of the above, the computing module is configured to be mounted on or near the static component.

In a further embodiment of any of the above, the computing module is configured to automatically update the position, orientation, and pitch of the sensor periodically.

In a further embodiment of any of the above, the static component is near an intersection or parking lot.

In a further embodiment of any of the above, the orientation of the sensor is measured as an angle relative to a global direction.

In a further embodiment of any of the above, the pitch of the sensor is measured as an angle relative to a vertical or horizontal direction.

In a further embodiment of any of the above, the position of the sensor is measured in a global coordinate system.

In another exemplary embodiment, a method of calibrating a sensor in an infrastructure system includes providing a sensor mounted to an infrastructure component. The sensor has a GPS antenna, an inclinometer, and a magnetometer. A current position of the sensor is detected with the GPS antenna. A current pitch of the sensor is detected with the inclinometer. A current orientation of the sensor is detected with the magnetometer. The current position, the current pitch, and the current orientation are stored.

In a further embodiment of any of the above, the current position of the sensor is stored in a local coordinate system.

In a further embodiment of any of the above, the current position of the sensor is stored in a global coordinate system.

In a further embodiment of any of the above, the orientation of the sensor is detected as an angle relative to a global direction.

In a further embodiment of any of the above, the pitch of the sensor is detected as an angle relative to a vertical or horizontal direction.

In a further embodiment of any of the above, the detecting and storing steps are repeated periodically.

In a further embodiment of any of the above, it is determined whether there is a fault based on at least one of the current position, the current pitch, and the current orientation. An operator is alerted when a fault is detected.

In a further embodiment of any of the above, the sensor is one of a radar sensor, a lidar sensor, and a camera.

### BRIEF DESCRIPTION OF THE DRAWINGS

The disclosure can be further understood by reference to the following detailed description when considered in connection with the accompanying drawings wherein:

FIG. 1 schematically illustrates an example smart infrastructure system.

FIG. 2 illustrates an example sensor according to an embodiment.

FIG. 3 schematically illustrates a top view of the example sensor.

FIG. 4 schematically illustrates a top view of the example sensor.

FIG. 5 schematically illustrates a side view of the example sensor.

FIG. 6 illustrates an example method of automatically calibrating the example sensor.

### DETAILED DESCRIPTION

The subject invention provides a system and method for calibrating a sensor for an infrastructure system. The sensor includes a magnetometer, inclinometer, and GPS antenna, which measure an orientation, pitch, and position, respectively, of the sensor. A method for calibrating a sensor includes detecting an orientation, pitch, and position of the sensor, and updating calibration information stored in a computing module.

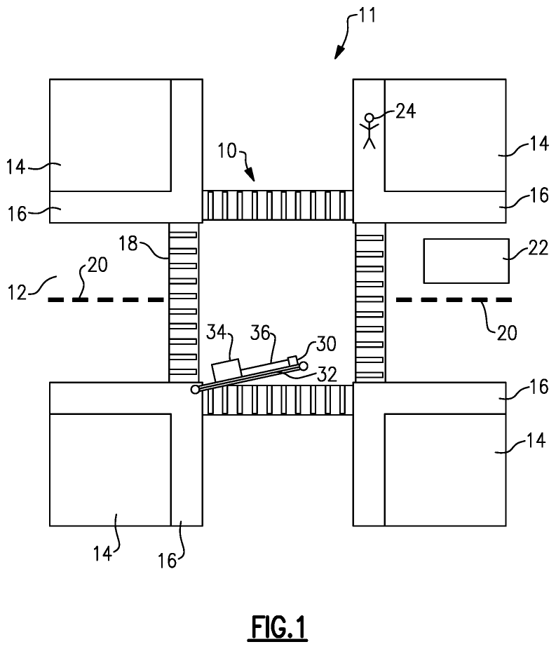

FIG. 1 illustrates an example smart infrastructure system 10 in an environment 11, such as an intersection. The environment 11 may contain roads 12, buildings 14, sidewalks 16, crosswalks 18, lane markers 20, vehicles 22, pedestrians 24, and street lights 32. Additional structures and/or objects may be present in the environment 11. The smart infrastructure system 10 may located in environments other than intersections, such as busy roads, mid-block crossings, or parking lots for example.

The system 10 generally includes a sensor 30 and a computing module 34 connected via communication hardware 36. In the illustrated example, the sensor 30 is mounted on a traffic light 32. In other examples, the sensor 30 may be mounted on a building 14, a street light, a sign, a parking meter, a telephone pole, or other structure in an area. The sensor 30 is statically mounted within the environment 11. The system 10 may include multiple sensors 30 mounted on the same or different structures, each of the sensors 30 in communication with the computing module 34. Although communication hardware 36 is illustrated, the sensor 30 and computing module 34 may communicate wirelessly. In other embodiments, the sensor 30 and computing module 34 may be integrated into a single unit.

The sensor 30 detects and tracks objects within the environment 11. The object may be a pedestrian 24 or vehicle 22, for example. The sensor 30 may be a camera, a radar sensor, or a lidar sensor, for example. The sensor 30 communicates the location of the objects in the environment 11 to the computing module 34. The computing module 34 may then send information regarding detected objects within the environment 11, such as pedestrians 24 or vehicles 22, to nearby vehicles via I2X or V2X communication. This information may be particularly useful for autonomous or semi-autonomous vehicles. The vehicle can receive information about a particular environment 11 from the system 10 earlier than it would otherwise be able to detect. The sensor 30 needs to be accurate in order to send accurate information to the computing module 34 and on to autonomous vehicles. Thus, the system 10 should be periodically calibrated to account for any shift in orientation and/or position of the sensor 30.

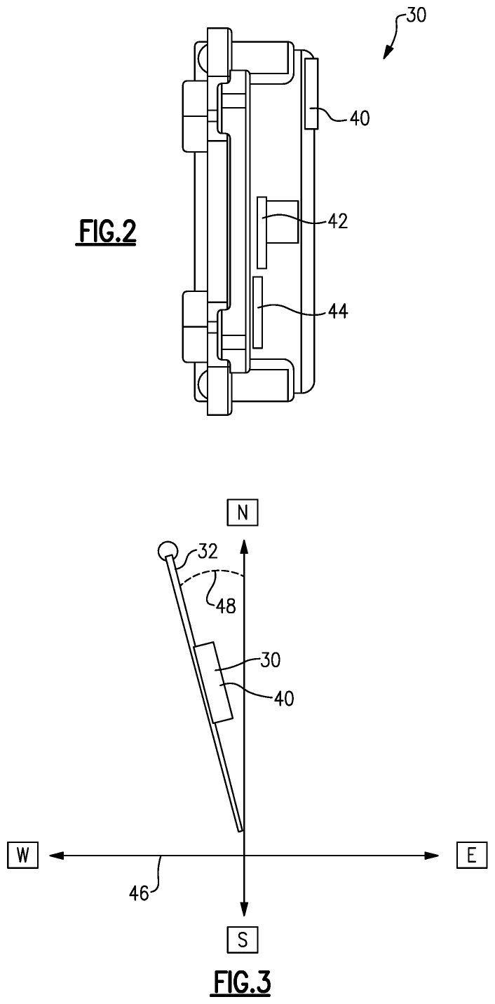

FIG. 2 illustrates an example sensor 30. The example sensor 30 includes a magnetometer 40, an inclinometer 42, and a GPS antenna 44. The magnetometer 40 measures a global rotation angle of the sensor 30 using the magnetic poles of the earth. The inclinometer 42 measures a pitch of the sensor 30 relative to a vertical direction. In this example, the vertical direction is substantially perpendicular to the ground of the environment 11. The inclinometer 42 may use radar, for example, to measure pitch. The GPS antenna 44 measures a geographical location of the sensor 30. The GPS antenna 44 may be observed by a static Global Navigation Satellite System (GNSS) to locate the sensor 30, for example. The magnetometer 40, inclinometer 42, and GPS antenna 44 determine and update calibration parameters for the sensor 30.

The position and orientation of the sensor 30 are stored in the computing module 34, and used to determine information about the position of any objects detected by the sensor 30. The sensor position 30 may be stored in a local coordinate system relative to the environment 11 and a known global position, or converted into a global coordinate system. The orientation of the sensor 30 may be calibrated in degrees from north, for example. The repeated calibration of the sensor 30 ensures that if the sensor 30 moves, such as the sensor 30 is disturbed by high winds or birds, for example, the position and orientation of the sensor 30 remain up to date.

The magnetometer 40, inclinometer 42, and GPS antenna 44 may periodically check the orientation and position of the sensor 30. In addition to maintaining accurate calibration data, this may also permit fault detection if the sensor 30 moves a large amount. For example, if a sensor mount breaks, or the sensor 30 is moved enough that it will no longer detect useful information, the sensor 30 can broadcast a fault to the computing module 34 to alert an operator. For example, if the sensor 30 moves a few degrees, but still has a full field of view of the environment 11, the calibration of the sensor 30 is updated in the computing module 34. If the sensor 30 falls or moves a significant amount, the computing module 34 may send a fault alert to an operator for the operator to come fix the sensor 30.

The computing module 34 may be calibrated to have data regarding the surrounding environment 11. For example, the computing module 34 may be calibrated to have information regarding cross walks 18, buildings 14, sidewalks 16, roads 12, lane markers 20, or other features within the environment 11. The sensors 30, 31 may communicate with the computing module 34 via communication hardware 36, or may communicate wirelessly. The system 10 may use one or more of the following connection classes, for example: WLAN connection, e.g. based on IEEE 802.11, ISM (Industrial, Scientific, Medical Band) connection, Bluetooth® connection, ZigBee connection, UWB (ultrawide band) connection, WiMax® (Worldwide Interoperability for Microwave Access) connection, infrared connection, mobile radio connection, and/or radar-based communication.

The system 10, and in particular the computing module 34, may include one or more controllers comprising a processor, memory, and one or more input and/or output (I/O) device interface(s) that are communicatively coupled via a local interface. The local interface can include, for example but not limited to, one or more buses and/or other wired or wireless connections. The local interface may have additional elements, which are omitted for simplicity, such as controllers, buffers (caches), drivers, repeaters, and receivers to enable communications. Further, the local interface may include address, control, and/or data connections to enable appropriate communications among the aforementioned components.

The computing module 34 may include a hardware device for executing software, particularly software stored in memory, such as an algorithm for sensor calibration. The computing module 34 may include a custom made or commercially available processor, a central processing unit (CPU), an auxiliary processor among several processors associated with the computing module 34, a semiconductor based microprocessor (in the form of a microchip or chip set), or generally any device for executing software instructions. The memory can include any one or combination of volatile memory elements (e.g., random access memory (RAM, such as DRAM, SRAM, SDRAM, VRAM, etc.)) and/or nonvolatile memory elements (e.g., ROM, hard drive, tape, CD-ROM, etc.). Moreover, the memory may incorporate electronic, magnetic, optical, and/or other types of storage media. Note that the memory can also have a distributed architecture, where various components are situated remotely from one another, but can be accessed by the processor.

The software in the memory may include one or more separate programs, each of which includes an ordered listing of executable instructions for implementing logical functions. A system component embodied as software may also be construed as a source program, executable program (object code), script, or any other entity comprising a set of instructions to be performed. When constructed as a source program, the program is translated via a compiler, assembler, interpreter, or the like, which may or may not be included within the memory.

The controller can be configured to execute software stored within the memory, to communicate data to and from the memory, and to generally control operations of the computing module 34 pursuant to the software. Software in memory, in whole or in part, is read by the processor, perhaps buffered within the processor, and then executed. This software may be used to determine and store the sensor orientation and position in the environment, for example.

FIG. 3 schematically illustrates a top view of the example sensor 30. The sensor 30 is arranged on the infrastructure component 32, and is oriented at an angle 48 relative to a global coordinate system 46. The global coordinate system 46 is relative to the magnetic poles of the earth. In one example, the angle 48 is measured as degrees from north. The magnetometer 40 measures the angle 48. The magnetometer 40 thus measures a global orientation angle, and sends the global orientation angle to the computing module 34.

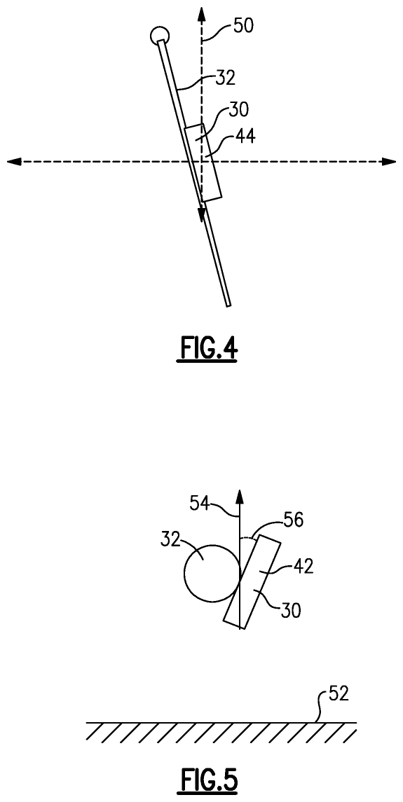

FIG. 4 schematically illustrates a top view of the example sensor 30. The GPS antenna 44 measures a geographical location of the sensor 30 relative to a coordinate system 50. The coordinate system 50 may be a global coordinate system, or a local coordinate system. The axes of the coordinate system 50 may be latitude and longitude, for example. The GPS antenna 44 may be observed by a GNSS, for example, to accurately geographically locate the sensor 30. The longer a GPS antenna 44 sits in one spot, the more accurate it becomes over time. Since the GPS antenna 44 is integrated into the sensor 30, which is statically mounted to an infrastructure component 32, it sits in the same place for awhile. This gives a very accurate geographical location. In some examples, a differential GPS (dGPS) antenna is not needed because of the stationary nature of the GPS antenna 44. This allows a cheaper GPS antenna 44 to be used in some examples.

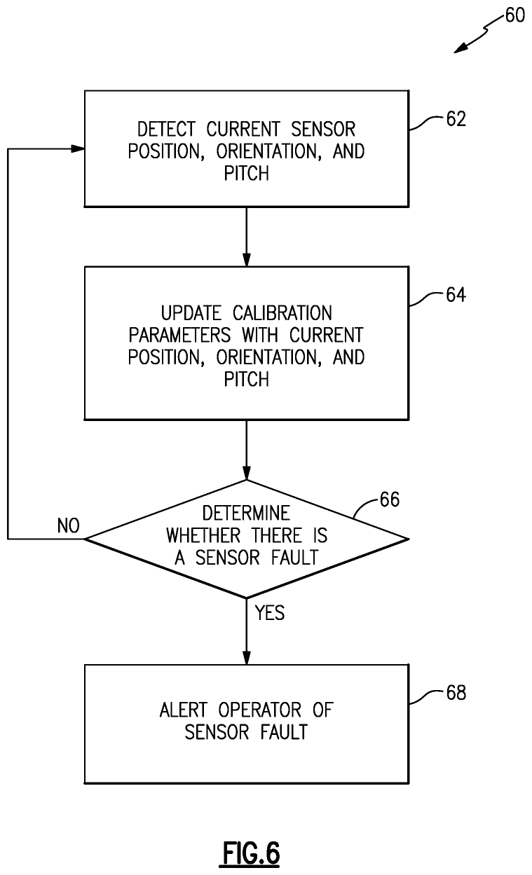

FIG. 5 schematically illustrates a side view of the example sensor 30. The inclinometer 42 measures an angle 56 of the sensor 30 relative to a vertical direction 54. The vertical direction 54 is substantially perpendicular to the ground 52. Thus, the inclinometer 42 measures the pitch of the sensor 30, and sends the information to the computing module 34. In other embodiments, the angle may be measured relative to a horizontal direction. For example, horizontal may be 0°, and the angle is positive or negative depending on whether the sensor 30 is viewing higher or lower than the horizontal direction. The computing module 34 can then determine whether the sensor 30 is looking at valid targets. If the pitch is off by a significant amount, such as the sensor 30 is looking at the ground or the sky, it can signal a failure.

FIG. 6 summarizes an example method 60 of calibrating the sensor 30. The current sensor position, orientation, and pitch are detected at 62. These may be detected by a GPS antenna 44, a magnetometer 40, and an inclinometer 42, for example. The GPS antenna 44, magnetometer 40, and inclinometer 42 may be integrated into the sensor 30. The position, orientation, and pitch are used to update calibration parameters at 64. This may be done by sending the position, orientation, and pitch to the computing module 34 and storing the position, orientation, and pitch. The calibration parameters of the sensor 30 ensure that the information detected by the sensor 30 and communicated to other systems is accurate. The computing module 34 may determine whether there is a sensor fault at 66. A sensor fault may be detected if the sensor 30 falls or is otherwise moved a large amount. In one example, a fault is detected when the sensor 30 is moved enough that the sensor 30 cannot gather useful information about the environment 11. If there is no sensor fault, the detecting and updating steps 62, 64 are repeated periodically. If a fault is detected at 66, the computing module 34 sends an alert to an operator at 68. This allows an operator to come and perform maintenance on the system 10 to correct the fault.

The disclosed system incorporates self-calibration into the sensor 30. This allows the sensor 30 to continuously update its calibration parameters, and detect faults. This system reduces the time and equipment required for manual calibration of known sensors. This system also detects faults and can alert an operator, so an operator can go fix the problem, improving the accuracy of the system 10.

It should also be understood that although a particular component arrangement is disclosed in the illustrated embodiment, other arrangements will benefit herefrom. Although particular step sequences are shown, described, and claimed, it should be understood that steps may be performed in any order, separated or combined unless otherwise indicated and will still benefit from the present invention.

Although the different examples have specific components shown in the illustrations, embodiments of this invention are not limited to those particular combinations. It is possible to use some of the components or features from one of the examples in combination with features or components from another one of the examples.

Although an example embodiment has been disclosed, a worker of ordinary skill in this art would recognize that certain modifications would come within the scope of the claims. For that reason, the following claims should be studied to determine their true scope and content.

What is claimed is:

1. A self-calibrating sensor system, comprising:
a sensor configured to be mounted to a static component, the sensor comprising:
a GPS antenna configured to detect a position of the sensor;
an inclinometer configured to detect a pitch of the sensor; and
a magnetometer configured to detect an orientation of the sensor.

2. The system of claim 1, wherein the sensor is one of a radar sensor, a lidar sensor, and a camera.

3. The system of claim 1, wherein the static component is an infrastructure component.

4. The system of claim 1, wherein the sensor is configured to be in communication with a computing module.

5. The system of claim 4, wherein the computing module is configured to store the position, pitch, and orientation of the sensor.

6. The system of claim 4, wherein the computing module is configured to communicate with a vehicle.

7. The system of claim 4, wherein the computing module is configured to be mounted on or near the static component.

8. The system of claim 4, wherein the computing module is configured to automatically update the position, orientation, and pitch of the sensor periodically.

9. The system of claim 1, wherein the static component is near an intersection or parking lot.

10. The system of claim 1, wherein the orientation of the sensor is measured as an angle relative to a global direction.

11. The system of claim 1, wherein the pitch of the sensor is measured as an angle relative to a vertical or horizontal direction.

12. The system of claim 1, wherein the position of the sensor is measured in a global coordinate system.

13. A method of calibrating a sensor in an infrastructure system, comprising:
providing a sensor mounted to an infrastructure component, the sensor having a GPS antenna, an inclinometer, and a magnetometer;
detecting a current position of the sensor with the GPS antenna, a current pitch of the sensor with the inclinometer, and a current orientation of the sensor with the magnetometer;
storing the current position, the current pitch, and the current orientation.

14. The method of claim 13, comprising storing the current position of the sensor in a local coordinate system.

15. The method of claim 13, comprising storing the current position of the sensor in a global coordinate system.

16. The method of claim 13, comprising detecting the orientation of the sensor as an angle relative to a global direction.

17. The method of claim 13, comprising detecting the pitch of the sensor as an angle relative to a vertical or horizontal direction.

18. The method of claim 13, comprising repeating the detecting and storing steps periodically.

19. The method of claim 13, comprising:
determining whether there is a fault based on at least one of the current position, the current pitch, and the current orientation; and
alerting an operator when a fault is detected.

20. The method of claim 13, wherein the sensor is one of a radar sensor, a lidar sensor, and a camera.
